(19) United States
(12) Patent Application Publication
(10) Pub. No.: US 2012/0164818 A1
(43) Pub. Date: Jun. 28, 2012

(54) Process for Cleaning Wafers

(75) Inventors: Soichi KUMON, Matsusaka-shi (JP); Takashi SAIO, Suzuka-shi (JP); Shinobu ARATA, Matsusaka-shi (JP); Masanori SAITO, Matsusaka-shi (JP); Hidehisa NANAI, Toshima-ku (JP); Yoshinori AKAMATSU, Matsusaka-shi (JP)

(73) Assignee: Central Glass Company, Limited, Ube-shi (JP)

(21) Appl. No.: 13/032,308

(22) Filed: Feb. 22, 2011

(30) Foreign Application Priority Data
Dec. 28, 2010 (JP) 2010-293853

(51) Int. Cl. H01L 21/322

(52) U.S. Cl. 438/476; 257/E21.317

(57) ABSTRACT

Disclosed is a process for cleaning a wafer having an uneven pattern at its surface. The process includes at least: a step of cleaning the wafer; a step of substituting a cleaning liquid retained in recessed portions of the wafer with a water-repellent liquid chemical after cleaning; and a step of drying the wafer. The process is characterized in that the cleaning liquid has a boiling point of 55 to 200° C., and characterized in that the water-repellent liquid chemical used for the substitution has a temperature of not lower than 40° C. and lower than a boiling point of the water-repellent liquid chemical thereby imparting water repellency at least to surfaces of the recessed portions. With this process, it is possible to provide a cleaning process for improving the cleaning step that tends to induce a pattern collapse.

### TECHNICAL FIELD

The present invention relates to a technique of cleaning a substrate (a wafer) in production of semiconductor devices or the like.

### BACKGROUND OF THE INVENTION

Semiconductor devices for use in networks or digital household electric appliances are being further desired to be sophisticated, multifunctional, and low in power consumption. Accordingly, the trend toward micro-patterning for circuits has been developed, with which micro-sizing of particles has so advanced as to cause reduction in production yield. As a result of this, a cleaning step for the purpose of removing contaminants such as the micro-sized particles and the like is frequently used. As a result of this, 30-40% of the whole of the semiconductor fabrication process is occupied with the cleaning step.

On the other hand, at the time of cleaning as conventionally performed with an ammonia-mixed cleaning agent, damages to a wafer due to the basicity has been getting serious together with the trend toward micro-patterning for circuits. Therefore, alternation with a less damaging one, i.e., a dilute hydrofluoric acid-based cleaning agent is taking place.

With this, problems about the damages to the wafer due to cleaning have been solved; however, problems due to an aspect ratio increased with the trend toward micro-processing in the semiconductor devices have become obvious. In other words, a phenomenon where the pattern causes a collapse when a gas-liquid interface passes through the pattern is brought about after cleaning or rinsing so as to largely reduce the yield, which has become a significant problem.

In Patent Publication 1, there is disclosed a technique of changing a cleaning liquid from water to 2-propanol before a gas-liquid interface passes through a pattern, as a method of suppressing the pattern collapse. However, it is said that there are limitations, for example, such a limitation that an aspect ratio of a pattern adaptable thereto is not higher than 5.

Additionally, in Patent Publication 2, there is disclosed a technique directed toward a resist pattern as a method for suppressing the pattern collapse. This is a method of decreasing a capillary force as far as possible thereby suppressing the pattern collapse. However, the thus disclosed technique is directed toward the resist pattern and is for reforming a resist itself. Moreover, the reformed surface of the resist can be finally removed together with the resist, so that it is not necessary to estimate a process of removing a treatment agent after drying; therefore, this technique cannot be applied to the present object.

Additionally, as a method of preventing the pattern collapse of semiconductor devices, there are suggested the use of a critical fluid, the use of liquid nitrogen and the like. In Patent Publication 3, a process for removing hardened photoresist, post-etch residue, and/or bottom anti-reflective coating (BARC) from a microelectronic device having the hardened photoresist, the post-etch residue, and/or the bottom anti-reflective coating (BARC) thereon is disclosed. The process includes a step of bringing the microelectronic device into contact with a dense fluid concentrate for sufficient time and under sufficient contacting conditions to at least partially remove the hardened photoresist, the post-etch residue, and/or BARC from the microelectronic device having the photoresist, the residue, and/or BARC thereon, in which the dense fluid concentrate contains at least one kind of co-solvent, optionally at least one kind of oxidizer/radical source, optionally at least one kind of surfactant, and optionally at least one kind of silicon-containing layer passivating agent, and in which the concentrate is further characterized by containing at least one of the following components (I) or (II):

(I) at least one kind of fluoride source and optionally at least one acid; and

(II) at least one kind of acid.

However, this process requires a specific cleaning device as compared to conventional cleaning steps, and difficult to apply to mass production because of its poor throughput and the like.

There is set forth in Patent Publications 4 and 5 a cleaning process for: surface-reforming a wafer surface provided to have an uneven pattern by a film containing silicon, by oxidation or the like; forming a water-repellent film on the surface by using a water-soluble surfactant or a silane coupling agent; reducing the capillary force; and thereby preventing the pattern collapse.

In Patent Publications 6 and 7, there is disclosed a surface treatment process including: a step of treating a surface of a resin pattern formed on a substrate or an etched pattern formed on the substrate by etching with a surface treatment liquid containing a silylation agent and a solvent; and a step of cleaning the resin pattern or the etched pattern obtained after the treatment with the surface treatment liquid.

Patent Publication 8 sets forth a cleaning process for semiconductor devices, the process including: a step of forming a semiconductor device comprised of a substrate and a dielectric layer having features protruding from the substrate; a step of cleaning the features of the semiconductor device with an aqueous solution; a step of replacing the aqueous solution with a first solvent after the cleaning; and a step of treating the features with a second solvent containing a hydrophobic treatment agent that reacts with sidewalls of the features to form a hydrophobic layer on surfaces of the sidewalls.

There is disclosed in Patent Publication 9 a process of cleaning a surface of a silicon wafer, the process using a cleaning agent for a silicon wafer which has a fine recess/projection pattern in the surface. The cleaning agent contains a cleaning liquid A and a cleaning liquid B. The cleaning liquid A is composed of an aqueous solution. The cleaning liquid B is used for providing recesses in the recess/projection pattern with water repellency, and is obtained by mixing water or an acidic aqueous solution with an alcohol solution which contains an alcohol solvent and a water-repellent compound containing a hydrophobic group and a hydrolyzable moiety which enables formation of a unit that is chemically bondable with silicon element in the silicon wafer. The water-repellent compound is blended to be 0.2-20% by mass per 100% by mass of the total of the cleaning liquid B, thereby providing a water-repellent cleaning liquid. With this, it is possible to present a capillary force of not higher than 2.1 MN/m² on the assumption that water is retained in the recesses formed at the surface of the silicon wafer provided with water repellency by the cleaning liquid B.

In Patent Publication 10, there is set forth a process of cleaning a surface of a silicon wafer having a fine uneven pattern at the surface, the process using a cleaning agent for the silicon wafer. The cleaning agent includes: at least a water-based cleaning liquid, and a water-repellent cleaning liquid for making at least recessed portions of the uneven pattern water-repellent during a cleaning step. The water-repellent cleaning liquid is a liquid composed of a water-repellent compound containing a reactive moiety which can chemically bind with silicon element in the silicon wafer, and a hydrophobic group, or is a liquid wherein 0.1 mass % or more of the water-repellent compound relative to the total quantity of 100 mass % of the water-repellent cleaning liquid and an organic solvent are mixed and contained therein, thereby achieving a capillary force of not higher than 2.1 MN/m² on the assumption that water is retained in the recessed portions formed at the surface of the silicon wafer provided with water repellency by the water-repellent cleaning liquid.

In Patent Publication 11, there is disclosed a process of cleaning a surface of a silicon wafer having a fine uneven pattern on the surface, the process using a cleaning agent for the silicon wafer. The cleaning agent for the silicon wafer includes at least a water-based cleaning liquid, and a water-repellent cleaning liquid for making at least recessed portions of the uneven pattern water-repellent during a cleaning step. The water-repellent cleaning liquid is a liquid mixedly containing a water-repellent compound which contains a reactive moiety which can chemically bind with silicon element in the silicon wafer and a hydrophobic group, and an organic solvent containing a nitrogen element-containing solvent. The water-repellent compound is mixedly contained at 0.1-50 mass % relative to the total quantity of 100 mass % of the water-repellent cleaning liquid. Furthermore, in the nitrogen element-containing solvent, an element bound to nitrogen is carbon. This allows presenting a capillary force of not higher than 2.1 MN/m² on the assumption that water is retained in the recessed portions formed at the surface of the silicon wafer provided with water repellency by the water-repellent cleaning liquid.

In Patent Publication 12, there is disclosed a process of cleaning a surface of a silicon wafer having a fine uneven pattern on the surface, the process using a cleaning agent for the silicon wafer. The cleaning agent for the silicon wafer is characterized by containing: at least an aqueous cleaning liquid; and a water-repellent cleaning liquid for providing at least recessed portions in the uneven pattern with water repellence during a cleaning step. The water-repellent cleaning liquid contains a mixture of a water-repellent compound which contains a hydrophobic group and a reactive moiety that is chemically bondable with silicon element of the silicon wafer, and an organic solvent that contains at least an alcohol solvent.

### REFERENCES ABOUT PRIOR ART

### Patent Publication

Patent Publication 1: Japanese Patent Application Publication No. 2008-198958
Patent Publication 2: Japanese Patent Application Publication No. 5-299336
Patent Publication 3: Japanese Patent Application Publication No. 2008-547050
Patent Publication 4: Japanese Patent No. 4403202
Patent Publication 5: Japanese Patent Application Publication No. 2010-114467
Patent Publication 6: Japanese Patent Application Publication No. 2010-129932
Patent Publication 7: International Application Publication 2010/047196 Pamphlet
Patent Publication 8: U.S. Patent Application Publication No. 2010/0122711
Patent Publication 9: International Application Publication 2010/074134 Pamphlet
Patent Publication 10: Japanese Patent Application Publication No. 2010-192878
Patent Publication 11: Japanese Patent Application Publication No. 2010-192879
Patent Publication 12: Japanese Patent Application Publication No. 2010-272852

### SUMMARY OF THE INVENTION

The present invention relates to a technique for cleaning a substrate (a wafer) in semiconductor device manufacturing and the like, the objective of which is to improve the production yield of devices having such a circuit pattern as to be particularly fine and particularly high in aspect ratio, and more particularly to a water-repellent liquid chemical and the like with the objective of improving a cleaning step which tends to induce a wafer having an uneven pattern at its surface to cause a collapse.

Patent Publications 4 and 5 disclose that the liquid temperature is increased by annealing treatment thereby accelerating a reaction of a surface treatment agent, but take it into account neither to quickly spread the surface treatment agent over the surface of an article to be treated nor to so accelerate the reaction of the surface treatment agent as to sufficiently form a coating even under an incompletely substituted condition, i.e., even under a condition where substitution is not completely achieved. Therefore, these have been susceptible to improvement in shortening the time involved in surface treatment. Additionally, Patent Publications 6 to 12 also have been susceptible to improvement in shortening the time involved in surface treatment, for the same reason.

The present invention is a process for cleaning a wafer, in which a water-repellent film is formed at least on surfaces of recessed portions of the wafer so as to reduce interaction between a liquid retained in the recessed portions and the surfaces of the recessed portions, thereby contributing to the prevention of the collapse of an uneven pattern. The present invention aims to provide a cleaning process which enables to economically and efficiently clean the wafer without impairing throughput.

A process for cleaning a wafer, according to the present invention is a process for cleaning a wafer having an uneven pattern at its surface. The process comprises the step of:

cleaning the wafer;

substituting a cleaning liquid retained in recessed portions of the wafer with a water-repellent liquid chemical after cleaning; and

drying the wafer,

wherein the cleaning liquid has a boiling point of 55 to 200° C., and

wherein the water-repellent liquid chemical used for the substitution has a temperature of not lower than 40° C. and lower than a boiling point of the water-repellent liquid chemical thereby imparting water repellency at least to surfaces of the recessed portions.

A pattern collapse occurs due to a gas-liquid interface that passes through a pattern when the wafer is dried. The reason thereof is said that a difference in height of residual liquid between a high-aspect ratio portion and a low-aspect ratio portion causes a difference in capillary force which acts on the pattern.

Accordingly, it is expected by decreasing the capillary force that the difference in capillary force due to the difference in height of residual liquid is reduced thereby resolving the pattern collapse. The magnitude of the capillary force is the absolute value of P obtained by the equation as represented below. From this equation, it is expected that the capillary force can be reduced by decreasing γ or cos θ.

P=2×γ×cos θ/S

(In the equation, γ represents the surface tension of a liquid retained in the recessed portions, θ represents the contact angle between a liquid retained in the recessed portions and the surfaces of the recessed portions, and S represents the widths of the recessed portions.)

The above-mentioned water-repellent liquid chemical can form the water-repellent film at least on the surfaces of the recessed portions of the uneven pattern to decrease a surface energy of the portion, thereby reducing the interaction between water or another liquid and the surface of the portion (i.e., at the interface), such as hydrogen bond, intermolecular forces and the like. The effect of reducing the interaction against water in particular is outstanding, but the effect of reducing the interaction is exhibited also in the case of a mixture liquid of water and a liquid other than water and in the case of a liquid other than water. With this, it is possible to increase the contact angle of the liquid to an article surface.

As discussed above, the cleaning liquid is substituted with the water-repellent liquid chemical. While the liquid chemical is being retained at least in the recessed portions of the uneven pattern, the water-repellent film is formed at least on the surfaces of the recessed portions of the uneven pattern. In other words, the uneven pattern is coated with the water-repellent film at least on the surfaces of the recessed portions when liquid is removed from or dried out of the recessed portions, so that the capillary force is lowered to make the pattern collapse difficult to occur.

Additionally, in order to form the water-repellent film at least on the surfaces of the recessed portions of the uneven pattern with a short time, it is effective to enhance a film-forming capability of the liquid chemical and to promptly substitute the cleaning liquid retained in the recessed portions with the water-repellent liquid chemical.

When the water-repellent liquid chemical has a temperature of not lower than 40° C., the reaction of the water-repellent liquid chemical is accelerated and the film-forming capability is enhanced. As a result, it becomes possible to form the water-repellent film with a short time. Additionally, it becomes possible to sufficiently form the water-repellent film even under an incompletely substituted condition, i.e., even if substitution is not completely accomplished. However, when the water-repellent liquid chemical has a temperature of the boiling point of the liquid chemical, the liquid chemical is immediately evaporable so as to easily bring the surface of the wafer dryness, which is therefore not preferable. Hence the water-repellent liquid chemical has a temperature of not lower than 40° C. and lower than the boiling point of the water-repellent liquid chemical, more preferably not lower than 50° C. and lower than a temperature represented by (the boiling point of the water-repellent liquid chemical-10° C.), much more preferably not lower than 70° C. and lower than a temperature represented by (the boiling point of the water-repellent liquid chemical-10° C.).

Additionally, when the cleaning liquid is one having a boiling point of 55 to 200° C., the cleaning liquid can readily evaporate at the time of supplying a water-repellent liquid chemical having a temperature of not lower than 40° C., so that the cleaning liquid retained in the recessed portions can be readily substituted with the water-repellent liquid chemical with a short time. As a result of this, it becomes possible to form the water-repellent film with a short time. Furthermore, since the water-repellent liquid chemical to be supplied has a temperature of not lower than 40° C. and lower than the boiling point of the liquid chemical, diffusion and convection tend to occur against the cleaning liquid that had been retained in the recessed portions of the uneven pattern, with which it becomes possible to substitute the cleaning liquid with the water-repellent liquid chemical with a short time. Therefore, the cleaning liquid is particularly preferably one having a boiling point of 50 to 180° C., much more preferably one having a boiling point of 70 to 160° C.

The cleaning liquid is preferably at least one liquid selected from the group consisting of organic solvents; water; and aqueous solutions obtained by mixing at least one kind selected from the organic solvents, acids, alkalis and oxidizing agents with water. Incidentally, water and the aqueous solutions obtained by mixing at least one kind selected from the group consisting of organic solvents, acids, alkalis and oxidizing agents with water are hereinafter sometimes referred to as a water-based liquid.

The water-repellent liquid chemical is used in the cleaning process in such a manner as to substitute the cleaning liquid with the liquid chemical. Additionally, the substituted water-repellent liquid chemical may be substituted with another cleaning liquid.

It is not necessary for the water-repellent film of the present invention to be formed continuously and uniformly; however, it is preferable to form it continuously and uniformly because a more excellent water repellency is obtained.

Additionally, the following wafer is a wafer containing silicon element at the surfaces of the recessed portions of the uneven pattern. The water-repellent liquid chemical contains a silicon compound A represented by the general formula [1]

R¹ₐSi(H)_{b}X_{4-a-b} [1]

(where R¹ mutually independently represents at least one group selected from a monovalent organic group having hydrocarbon group with 1 to 18 carbon atoms and a monovalent organic group having a fluoroalkyl chain with 1 to 8 carbon atoms, X mutually independently represents a monovalent organic group of which element to be bonded to Si element is nitrogen, a is an integer of from 1 to 3, b is an integer of from 0 to 2, and the total of a and b is 1 to 3),

or the silicon compound A and a silicon compound B. It is preferable that the silicon compound B is at least one selected from the group consisting of trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate and octyldimethylsilyl trifluoromethanesulfonate.

The water-repellent film is formed by reacting X represented in the above-mentioned general formula [1] with silanol group that serves as a reaction site of the wafer surface thereby chemically bonding the silicon compound A to silicon element of the silicon wafer. R¹ shown in the above-mentioned general formula [1] decreases a surface energy of the recessed portions so as to reduce the interaction between water or another liquid and the surface of the water-repellent film (i.e., at the interface), such as hydrogen bond, intermolecular forces and the like, thereby allowing increasing the contact angle of liquid to an article surface.

The silicon compound B, i.e., at least one selected from the group consisting of trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate and octyldimethylsilyl trifluoromethanesulfonate, contributes to acceleration of the reaction between the silicon compound A and silicon element of the silicon wafer. The presence of the silicon compound B in the liquid chemical makes it possible to form a water-repellent film with a short time. Incidentally, the rate of forming the water-repellent film on a substrate surface, i.e. the rate at which the surface of the substrate exhibits water repellency is determined by the rate at which a component constituting the silicon compound A is bonded to the reaction site of the substrate surface. In the presence of the silicon compound B, the component constituting the silicon compound A can be rapidly reacted with silanol group serving as the reaction site of the unevenly patterned surface of the silicon wafer, so that water repellency is sufficiently provided to the substrate surface with a short time during surface treatment. Incidentally, the silicon compound B may constitute a part of the water-repellent film.

Additionally, it is preferable that the silicon compound A is at least one selected from the group consisting of hexamethyldisilazane, trimethylsilyl dimethylamine, trimethylsilyl diethylamine, tetramethyldisilazane, dimethylsilyl dimethylamine, dimethylsilyl diethylamine, 1,3-dibutyltetramethyldisilazane, butyldimethylsilyl dimethylamine, butyldimethylsilyl diethylamine, 1,3-dihexyltetramethyldisilazane, hexyldimethylsilyl dimethylamine, hexyldimethylsilyl diethylamine, 1,3-dioctyltetramethyldisilazane, octyldimethylsilyl dimethylamine and octyldimethylsilyl diethylamine.

### BRIEF EXPLANATION OF THE DRAWINGS

FIG. 1 A schematic plan view of a wafer 1 whose surface is made into a surface formed having an uneven pattern 2.

FIG. 2 A view showing a part of a-a′ cross section of FIG. 1.

FIG. 3 A schematic view showing a condition where a cleaning liquid 8 is retained in recessed portions 4 in a cleaning step.

FIG. 4 A schematic view showing a condition where a water-repellent liquid chemical 9 is supplied to the wafer in which the cleaning liquid 8 is retained in the recessed portions 4 in the cleaning step.

FIG. 5 A schematic view showing a condition where the water-repellent liquid chemical 9 is retained in the recessed portions 4 thereby forming a water-repellent film 12 in the cleaning step.

### DETAILED DESCRIPTION

In a cleaning process of the present invention, a water-repellent film is formed on surfaces of recessed portions of a wafer so as to reduce the interaction between a liquid retained in the recessed portions and the surfaces of the recessed portions, with which it is possible to form the water-repellent film contributing to the prevention of the collapse of an uneven pattern, in a short time. Accordingly, a process for producing a wafer formed having an unevenly patterned surface by using a water-repellent liquid chemical of the present invention is excellent in productivity.

The present invention is a process for cleaning a wafer having an uneven pattern at its surface. The process comprises the step of;
cleaning the wafer;
substituting a cleaning liquid retained in recessed portions of the wafer with a water-repellent liquid chemical after cleaning; and
drying the wafer,
wherein the cleaning liquid has a boiling point of 55 to 200° C., and
wherein the water-repellent liquid chemical used for the substitution has a temperature of not lower than 40° C. and lower than a boiling point of the water-repellent liquid chemical thereby imparting water repellency at least to surfaces of the recessed portions.

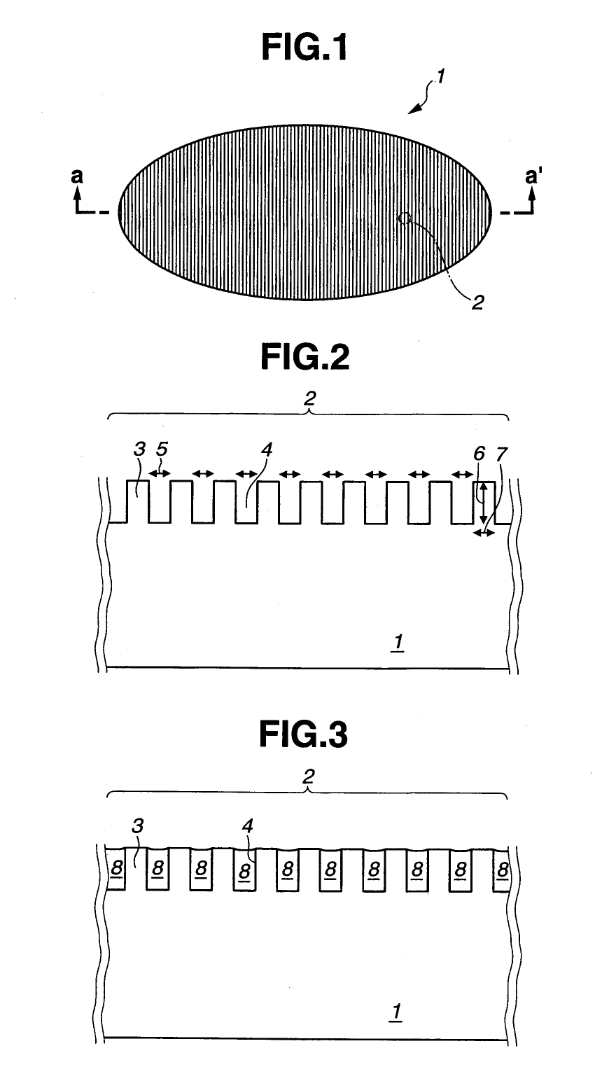

The wafer formed having the uneven pattern at its surface is cleaned with a various kinds of liquids and then the liquids are removed therefrom by drying or the like, wherein if the recessed portions have small widths and projected portions have large aspect ratios, a pattern collapse is to easily occur. The uneven pattern is defined as shown in FIG. 1 and FIG. 2. FIG. 1 is a schematic plan view showing an example of a wafer 1 whose surface is made into a surface formed having an uneven pattern 2. FIG. 2 is a view showing a part of a-a′ cross section of FIG. 1. Widths 5 of recessed portions are defined by intervals between adjacent projected portions 3, as shown in FIG. 2. The aspect ratios of projected portions are expressed by dividing heights 6 of the projected portions by widths 7 of the projected portions. The pattern collapse found in the cleaning step is to easily occur when the recessed portions have widths of not more than 70 nm, particularly not more than 45 nm and when the aspect ratios are not less than 4, particularly not less than 6.

In the cleaning process of the present invention, the cleaning liquid having a boiling point of from 55 to 200° C. is retained at least in the recessed portions of the uneven pattern and then substituted with the water-repellent liquid chemical under a condition where the cleaning liquid is retained at least in the recessed portions of the uneven pattern.

FIG. 3 is a schematic view showing a condition where a cleaning liquid 8 is retained in recessed portions 4. The wafer drawn in the schematic view of FIG. 3 shows a part of the a-a′ cross section in FIG. 1. At the cleaning step, the water-repellent liquid chemical is supplied to the wafer which is in a condition where the recessed portions are retaining the cleaning liquid 8 therein.

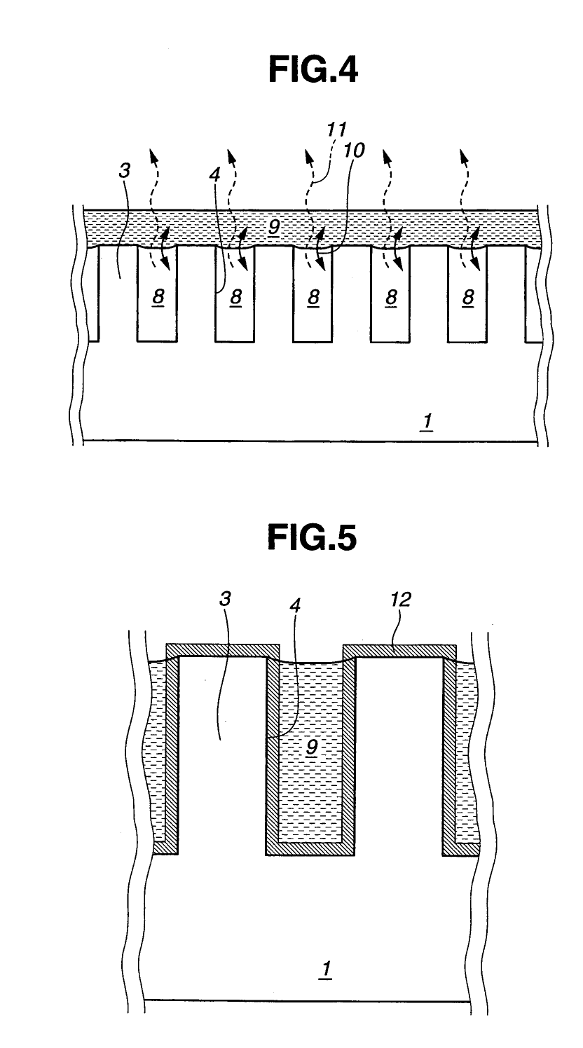

FIG. 4 is a schematic view showing a condition where a water-repellent liquid chemical 9 is supplied to the wafer which is in a condition where the cleaning liquid 8 is retained in the recessed portions 4. At the time of conducting substitution of the cleaning liquid 8 with the water-repellent liquid chemical 9, the cleaning liquid 8 has a boiling point of 55 to 200° C. and the water-repellent liquid chemical 9 is heated to be not lower than 40° C. and to be lower than a boiling point of the water-repellent liquid chemical. Hence the mixing of the cleaning liquid and the water-repellent liquid chemical tends to readily proceed, for example, by virtue of diffusion or convection represented by 10 in this figure, while evaporation of the cleaning liquid represented by 11 in this figure becomes readily advanced. As a result, the substitution can be developed in a short time.

FIG. 5 is a schematic view showing a condition where the water-repellent liquid chemical 9 is retained in the recessed portions 4 so that a water-repellent film 12 is formed in the cleaning step. The water-repellent film 12 is formed on surfaces of the recessed portions 4, with which the surfaces obtain water repellency.

Additionally, the water-repellent liquid chemical contains a silicon compound A represented by the general formula [1]

R¹ₐSi(H)_{b}X_{4-a-b} [1]

(where R¹ mutually independently represents at least one group selected from a monovalent organic group having hydrocarbon group with 1 to 18 carbon atoms and a monovalent organic group having a fluoroalkyl chain with 1 to 8 carbon atoms, X mutually independently represents a monovalent organic group of which element to be bonded to Si element is nitrogen, a is an integer of from 1 to 3, b is an integer of from 0 to 2, and the total of a and b is 1 to 3),

or the silicon compound A and a silicon compound B. It is preferable that the silicon compound B is at least one selected from the group consisting of trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate and octyldimethylsilyl trifluoromethanesulfonate.

In the above-mentioned general formula [1], the monovalent organic group of which element to be bonded to Si element is nitrogen, represented as X, may include not only hydrogen, carbon, nitrogen and oxygen element but also silicon, sulfur, a halogen element, and the like. Examples of the monovalent organic group of which element to be bonded to Si element is nitrogen are isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring (the following formula [2]), oxazolidinone ring (the following formula [3]), morpholine ring (the following formula [4]), —NH—C(O)—Si(CH₃)₃, —N(H)_{2-c}(Si(H)_{d}R²_{3-d})_{c} (where R² is a monovalent hydrocarbon group with 1 to 18 carbon atoms, of which hydrogen element may be partially or entirely substituted with fluorine element; cis an integer of 1 or 2; and d is an integer of from 0 to 2), and the like. Such a silicon compound A rapidly reacts at its reactive moiety with silanol group serving as a reaction site of the unevenly patterned surface of the silicon wafer so as to chemically bond the silicon compound A to silicon element of the silicon wafer through siloxane bond, with which it becomes possible to coat a wafer surface with hydrophobic R¹ groups thereby allowing decreasing the capillary force of the surfaces of the recessed portions of the wafer in a short time.

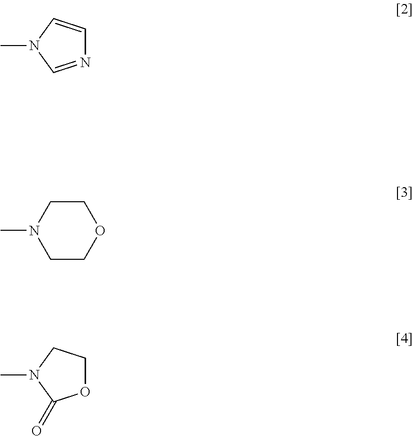

Additionally, it is more preferable that the number of X of the silicon compound A, which is represented by 4-a-b, is 1, because water-repellent film is evenly formed thereby.

It is preferable that IV of the general formula [1] mutually independently represents at least one group selected from CₘH₂ₘ₊₁ (m=1 to 18) and CₙF₂ₙ₊₁CH₂CH₂ (n=1 to 8), because the wettability of the unevenly patterned surface can be more reduced when the water-repellent film is formed thereon, i.e. because a more excellent water repellency can be imparted to the surface. Additionally, it is preferable that m and n are from 1 to 8 because the water-repellent film can be formed on the unevenly patterned surface in a short time.

Examples of the silicon compound A represented by the general formula [1] are aminosilanes such as CH₃Si(NH₂)₃, C₂H₅Si(NH₂)₃, C₃H₇Si(NH₂)₃, C₄H₉Si(NH₂)₃, C₅H₁₁Si(NH₂)₃, C₆H₁₃Si(NH₂)₃, C₇H₁₅Si(NH₂)₃, C₈H₁₇Si(NH₂)₃, C₉H₁₉Si(NH₂)₃, C₁₀H₂₁Si(NH₂)₃, C₁₁H₂₃Si(NH₂)₃, C₁₂H₂₅Si(NH₂)₃, C₁₃H₂₇Si(NH₂)₃, C₁₄H₂₉Si(NH₂)₃, C₁₅H₃₁Si(NH₂)₃, C₁₆H₃₃Si(NH₂)₃, C₁₇H₃₅Si(NH₂)₃, C₁₈H₃₇Si(NH₂)₃, (CH₃)₂Si(NH₂)₂, C₂H₅Si(CH₃)(NH₂)₂, (C₂H₅)₂Si(NH₂)₂, C₃H₇Si(CH₃)(NH₂)₂, (C₃H₇)₂Si(NH₂)₂, C₄H₉Si(CH₃)(NH₂)₂, (C₄H₉)₂Si(NH₂)₂, C₅H₁₁Si(CH₃)(NH₂)₂, C₆H₁₃Si(CH₃)(NH₂)₂, C₇H₁₅Si(CH₃)(NH₂)₂, C₈H₁₇Si(CH₃)(NH₂)₂, C₉H₁₉Si(CH₃)(NH₂)₂, C₁₀H₂₁Si(CH₃)(NH₂)₂, C₁₁H₂₃Si(CH₃)(NH₂)₂, C₁₂H₂₅Si(CH₃)(NH₂)₂, C₁₃H₂₇Si(CH₃)(NH₂)₂, C₁₄H₂₉Si(CH₃)(NH₂)₂, C₁₅H₃₁Si(CH₃)(NH₂)₂, C₁₆H₃₃Si(CH₃)(NH₂)₂, C₁₇H₃₅Si(CH₃)(NH₂)₂, C₁₈H₃₇Si(CH₃)(NH₂)₂, (CH₃)₃SiNH₂, C₂H₅Si(CH₃)₂NH₂, (C₂H₅)₂Si(CH₃)NH₂, (C₂H₅)₃SiNH₂, C₃H₇Si(CH₃)₂NH₂, (C₃H₇)₂Si(CH₃)NH₂, (C₃H₇)₃SiNH₂, C₄H₉Si(CH₃)₂NH₂, (C₄H₉)₃SiNH₂, C₅H₁₁Si(CH₃)₂NH₂, C₆H₁₃Si(CH₃)₂NH₂, C₇H₁₅Si(CH₃)₂NH₂, C₈H₁₇Si(CH₃)₂NH₂, C₉H₁₉Si(CH₃)₂NH₂, C₁₀H₂₁Si(CH₃)₂NH₂, C₁₁H₂₃Si(CH₃)₂NH₂, C₁₂H₂₅Si(CH₃)₂NH₂, C₁₃H₂₇Si(CH₃)₂NH₂, C₁₄H₂₉Si(CH₃)₂NH₂, C₁₅H₃₁Si(CH₃)₂NH₂, C₁₆H₃₃Si(CH₃)₂NH₂, C₁₇H₃₅Si(CH₃)₂NH₂, C₁₈H₃₇Si(CH₃)₂NH₂, (CH₃)₂Si(H)NH₂, CH₃Si(H)₂NH₂, (C₂H₅)₂Si(H)NH₂, C₂H₅Si(H)₂NH₂, C₂H₅Si(CH₃)(H)NH₂, (C₃H₇)₂Si(H)NH₂, C₃H₇Si(H)₂NH₂, CF₃CH₂CH₂Si(NH₂)₃, C₂F₅CH₂CH₂Si(NH₂)₃, C₃F₇CH₂CH₂Si(NH₂)₃, C₄F₉CH₂CH₂Si(NH₂)₃, C₅F₁₁CH₂CH₂Si(NH₂)₃, C₆F₁₃CH₂CH₂Si(NH₂)₃, C₇F₁₅CH₂CH₂Si(NH₂)₃, C₈F₁₇CH₂CH₂Si(NH₂)₃, CF₃CH₂CH₂Si(CH₃)(NH₂)₂, C₂F₅CH₂CH₂Si(CH₃)(NH₂)₂, C₃F₇CH₂CH₂Si(CH₃)(NH₂)₂, C₄F₉CH₂CH₂Si(CH₃)(NH₂)₂, C₅F₁₁CH₂CH₂Si(CH₃)(NH₂)₂, C₆F₁₃CH₂CH₂Si(CH₃)(NH₂)₂, C₇F₁₅CH₂CH₂Si(CH₃)(NH₂)₂, C₈F₁₇CH₂CH₂Si(CH₃)(NH₂)₂, CF₃CH₂CH₂Si(CH₃)₂NH₂, C₂F₅CH₂CH₂Si(CH₃)₂NH₂, C₃F₇CH₂CH₂Si(CH₃)₂NH₂, C₄F₉CH₂CH₂Si(CH₃)₂NH₂, C₅F₁₁CH₂CH₂Si(CH₃)₂NH₂, C₆F₁₃CH₂CH₂Si(CH₃)₂NH₂, C₇F₁₅CH₂CH₂Si(CH₃)₂NH₂, C₈F₁₇CH₂CH₂Si(CH₃)₂NH₂, CF₃CH₂CH₂Si(CH₃)(H)NH₂ and the like; those obtained by substituting amino group (—NH₂ group) of the aminosilanes with —N═C═O, —N(CH₃)₂, —N(C₂H₅)₂, —N═C═S, —N₃, —NHC(O)CH₃, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —N(H)_{2-c}(Si(H)_{d}R²_{3-d})_{c} (where R² is a monovalent hydrocarbon group with 1 to 18 carbon atom, in which hydrogen element is partially or entirely substitutable with fluorine element. c is an integer of 1 or 2. d is an integer of from 0 to 2); and the like.

Among these, the silicon compound A is particularly preferably hexamethyldisilazane, trimethylsilyl dimethylamine, trimethylsilyl diethylamine, tetramethyldisilazane, dimethylsilyl dimethylamine, dimethylsilyl diethylamine, 1,3-dibutyltetramethyldisilazane, butyldimethylsilyl dimethylamine, butyldimethylsilyl diethylamine, 1,3-dihexyltetramethyldisilazane, hexyldimethylsilyl dimethylamine, hexyldimethylsilyl diethylamine, 1,3-dioctyltetramethyldisilazane, octyldimethylsilyl dimethylamine or octyldimethylsilyl diethylamine.

The silicon compound B acts as a catalyst for receiving electrons from the silicon compound A to accelerate the reaction between the silicon compound A and silanol group serving as the reaction site of the surface of the silicon wafer thereby chemically bonding the silicon compound A to silicon element of the silicon wafer through siloxane bond. The presence of the silicon compound B in the liquid chemical allows forming a water-repellent film with a short time. Additionally, the silicon compound B may constitute a part of the water-repellent film.

The silicon compound B may be obtained by a reaction. For example, it may be obtained by reacting a silicon compound C represented by the following general formula [5] with at least one selected from the group consisting of trifluoroacetic acid, trifluoroacetic anhydride, trifluoromethanesulfonic acid and trifluoromethanesulfonic anhydride (hereinafter, the one is sometimes referred to as “acid C”).

R³ₑ(H)_{f}Si—Y_{4-e-f} [5]

(In the formula [5], R³ₑ(H)_{f}Si— represents one selected from the group consisting of (CH₃)₃Si—, (CH₃)₂(H)Si—, (C₄H₉)(CH₃)₂Si—, (C₆H₁₃)(CH₃)₂Si— and (C₈H₁₇)(CH₃)₂Si—. Additionally, Y mutually independently represents a monovalent organic group of which element to be bonded to Si element is nitrogen.)

Incidentally, a liquid chemical prepared in such a manner as to produce the silicon compound B by using at least one selected from trifluoroacetic anhydride and trifluoromethanesulfonic anhydride as the acid C and reacting it with the silicon compound C, or a liquid chemical prepared by using the silicon compound A and the silicon compound B as the starting material is more preferable, because it is excellent in stability.

The liquid chemical for forming the water-repellent film, according to the present invention may be one in which the silicon compound C is excessively added relative to the acid C and in which an excess of the silicon compound C that is not consumed by the reaction serves as the silicon compound A to contribute to the formation of the water-repellent film. Incidentally, the number of moles of the silicon compound C is preferably 0.2 to 100000 times, more preferably 0.5 to 50000 times, much more preferably 1 to 10000 times the number of moles of the acid C.

Incidentally, a reaction other than the reaction between the silicon compound C and the acid C may be adopted so long as it is possible to obtain the silicon compound B.

The monovalent organic group of which element to be bonded to Si element is nitrogen, represented as Y of the silicon compound C of the general formula [5], may include not only hydrogen, carbon, nitrogen and oxygen element but also silicon, sulfur, a halogen element and the like. Examples of the monovalent organic group of which element to be bonded to Si element is nitrogen are isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —N(H)_{2-g}(Si(H)ₕR⁴₃₋ₕ)_{g} (where R⁴ is a monovalent hydrocarbon group with 1 to 18 carbon atoms, of which hydrogen element may be partially or entirely substituted with fluorine element; g is an integer of 1 or 2; and h is an integer of from 0 to 2), and the like.

Examples of the silicon compound C represented by the general formula [5] are: aminosilanes such as (CH₃)₃SiNH₂, C₄H₉Si(CH₃)₂NH₂, C₆H₁₃Si(CH₃)₂NH₂, C₈H₁₇Si(CH₃)₂NH₂ and (CH₃)₂Si(H)NH₂ and the like; those obtained by substituting amino group (—NH₂ group) of the aminosilanes with —N═C═O, —N(CH₃)₂, —N(C₂H₅)₂, —N═C═S, —N₃, —NHC(O)CH₃, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —NH—Si(CH₃)₃, —NH—Si(H)(CH₃)₂, —NH—Si(CH₃)₂(C₄H₉), —NH—Si(CH₃)₂(C₆H₁₃), —NH—Si(CH₃)₂(C₈H₁₇), or. —N—{Si(CH₃)₃}₂; and the like.

Among these, the silicon compound C represented by the general formula [5] is preferably the silicon compound A.

For example, when mixing hexamethyldisilazane as the silicon compound C and trifluoroacetic anhydride as the acid C, the trifluoroacetic anhydride immediately reacts therewith thereby forming trimethylsilyl trifluoroacetate as the silicon compound B.

Additionally, for example when mixing hexamethyldisilazane as the silicon compound C and trifluoromethanesulfonic anhydride as the acid C, the trifluoromethanesulfonic anhydride immediately reacts therewith thereby forming trimethylsilyl trifluoromethanesulfonate as the silicon compound B.

Additionally, for example when mixing tetramethyldisilazane as the silicon compound C and trifluoroacetic anhydride as the acid C, the trifluoroacetic anhydride immediately reacts therewith thereby forming dimethylsilyl trifluoroacetate as the silicon compound B.

Additionally, for example when mixing tetramethyldisilazane as the silicon compound C and trifluoromethanesulfonic anhydride as the acid C, the trifluoromethanesulfonic anhydride immediately reacts therewith thereby forming dimethylsilyl trifluoromethanesulfonate as the silicon compound B.

Additionally, for example when mixing 1,3-dibutyltetramethyldisilazane as the silicon compound C and trifluoroacetic anhydride as the acid C, the trifluoroacetic anhydride immediately reacts therewith thereby forming butyldimethylsilyl trifluoroacetate as the silicon compound B.

Additionally, for example when mixing 1,3-dibutyltetramethyldisilazane as the silicon compound C and trifluoromethanesulfonic anhydride as the acid C, the trifluoromethanesulfonic anhydride immediately reacts therewith thereby forming butyldimethylsilyl trifluoromethanesulfonate as the silicon compound B.

Additionally, for example when mixing 1,3-dioctyltetramethyldisilazane as the silicon compound C and trifluoroacetic anhydride as the acid C, the trifluoroacetic anhydride immediately reacts therewith thereby forming octyldimethylsilyl trifluoroacetate as the silicon compound B.

Additionally, for example when mixing 1,3-dioctyltetramethyldisilazane as the silicon compound C and trifluoromethanesulfonic anhydride as the acid C, the trifluoromethanesulfonic anhydride immediately reacts therewith thereby forming octyldimethylsilyl trifluoromethanesulfonate as the silicon compound B.

In the liquid chemical, the silicon compound B preferably has a concentration of from 0.01 to 20 mass % relative to the total quantity of 100 mass % of the silicon compound A. A low concentration is poor in the effect of the silicon compound B. An excessively high concentration does not improve the effect of the silicon compound B, and if anything, raises the fear of erosion of the wafer surface. In view of this, the concentration of the silicon compound B is particularly preferably from 0.05 to 15 mass % relative to the total quantity of 100 mass % of the silicon compound A.

Furthermore, in the liquid chemical, the silicon compound A and the silicon compound B may be diluted with a solvent. The total addition quantity of the silicon compound A and the silicon compound B is preferably from 0.1 to 100 mass % relative to the total quantity of 100 mass % of the liquid chemical because the water-repellent film can be readily and uniformly formed at least on the surfaces of the recessed portions of the uneven pattern. When it is less than 0.1 mass %, the effect of protecting the uneven pattern tends to become insufficient. It is more preferably from 0.5 to 50 mass %, much more preferably from 1 to 30 mass %.

As the solvent which may be used in the liquid chemical for dilution, suitably adoptable examples are organic solvents such as hydrocarbons, esters, ethers, ketones, halogen element-containing solvents, sulfoxide-based solvents, alcohols, derivatives of polyalcohols, nitrogen element-containing solvents, a mixture liquid of these, and the like. Among these, it is preferable to use hydrocarbons, esters, ethers, halogen element-containing solvents, derivatives of polyalcohols having no OH group or a mixture of these, since the water-repellent film can be formed on the unevenly patterned surface with a short time.

Examples of hydrocarbons are toluene, benzene, xylene, hexane, heptane, octane and the like. Examples of esters are ethyl acetate, propyl acetate, butyl acetate, ethyl acetoacetate and the like. Examples of ethers are diethyl ether, dipropyl ether, dibutyl ether, tetrahydrofuran, dioxane and the like. Examples of the halogen element-containing solvents are: perfluorocarbons such as perfluorooctane, perfluorononane, perfluorocyclopentane, perfluorocyclohexane, hexafluorobenzene and the like; hydrofluorocarbons such as 1,1,1,3,3-pentafluorobutane, octafluorocyclopentane, 2,3-dihydrodecafluoropentane, ZEORORA-H (produced by ZEON CORPORATION) and the like; hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec HFE-7100, Novec HFE-7200, Novec 7300, Novec 7600 (any of these are produced by 3M Limited) and the like; chlorocarbons such as tetrachloromethane and the like; hydrochlorocarbons such as chloroform and the like; chlorofluorocarbons such as dichlorodifluoromethane and the like; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifluoropropene and the like; perfluoroethers; perfluoropolyethers; and the like. Examples of the derivatives of polyalcohols having no OH group are diethylene glycol monoethyl ether acetate, ethylene glycol monomethyl ether acetate, ethylene glycol monobutyl ether acetate, propylene glycol monomethyl ether acetate, propylene glycol monoethyl ether acetate, diethylene glycol dimethyl ether, diethylene glycol ethylmethyl ether, diethylene glycol diacetate, ethylene glycol diacetate, ethylene glycol diethyl ether, ethylene glycol dimethyl ether and the like.

In the cleaning process of the present invention, the water-repellent liquid chemical is provided with a temperature of not lower than 40° C. It is therefore preferable that the solvent that may be used in the liquid chemical for dilution is one having a boiling point of not lower than 40° C. Incidentally, in the case of using a solvent having a boiling point of lower than 40° C., it may be mixed with another one having a boiling point exceeding 40° C. thereby preparing a mixture solvent having a boiling point of not lower than 40° C. It is more preferable that the boiling point of the solvent is not lower than 50° C., much more preferably not lower than 70° C.

Additionally, it is preferable to use a uninflammable one as the solvent that may be used for dilution since the water-repellent liquid chemical becomes uninflammable or increases in flash point so as to reduce the risk of the liquid chemical. Most of the halogen element-containing solvents are uninflammable, and such halogen element-containing uninflammable solvents can be preferably used as an uninflammable organic solvent. The water-repellent liquid chemical used in the cleaning process of the present invention is heated, which is effective at lowering the flammability of the liquid chemical.

If the solvent that may be used for dilution has a low boiling point in a case of providing the water-repellent liquid chemical to the wafer while rotating the wafer, the water-repellent liquid chemical tends to dry up before wetly spreading all over the wafer. Additionally, in a case where the boiling point is high, the viscosity tends to so increase that the liquid chemical becomes difficult to wetly spread all over the wafer. It is therefore preferable to use a solvent having a boiling point of 80 to 220° C. Taking the cost or the compatibility with other cleaning liquids into account, the solvent is preferably diethylene glycol monoethyl ether acetate, ethylene glycol monomethyl ether acetate, propylene glycol monomethyl ether acetate, diethylene glycol dimethyl ether, diethylene glycol ethylmethyl ether, ethylene glycol diacetate or ethylene glycol dimethyl ether. Particularly, acetate-based solvents such as propylene glycol monomethyl ether acetate and the like are preferable.

Additionally, the water-repellent liquid chemical preferably has a total quantity of the water content in the starting material of not higher than 5000 mass ppm relative to the total quantity of the raw material. In a case where the total quantity of the water content exceeds 5000 mass ppm, the effect of the silicon compound A is so reduced as to make it difficult to form the water-repellent film in a short time. Accordingly, the smaller the water content in the liquid chemical, the more preferable it is; and more particularly, it is preferably not higher than 1000 mass ppm, much more preferably not higher than 500 mass ppm. Incidentally, the water content in the liquid chemical may be not lower than 5 mass ppm.

Additionally, the water-repellent liquid chemical may contain additives or the like, in addition to the silicon compound A represented by the general formula [1], the silicon compound B and the solvent. As the additives, it is possible to cite oxidizing agents such as hydrogen peroxide, ozone and the like, surfactants, and the like. Additionally, in a case where the uneven pattern of the wafer has a part formed of a material on which the silicon compound A cannot form the water-repellent film, that which can form the water-repellent film on the material may be added. Furthermore, another acid may be added for other purposes than the purpose of obtaining the silicon compound B.

Additionally, as the water-repellent liquid chemical, there can be used those containing a mixture of: 76 to 99.8999 mass % of at least one kind of organic solvent selected from the group consisting of hydrofluorocarbon, hydrofluoroether, perfluorocarbon, hydrochlorofluorocarbon, ethylene glycol monomethyl ether acetate and propylene glycol monomethyl ether acetate; 0.1 to 20 mass % of at least one kind of silazane compound selected from the group consisting of hexamethyldisilazane and tetramethyldisilazane; and 0.0001 to 4 mass % of at least one kind of acid selected from the group consisting of trimethylsilyl trifluoroactate and dimethylsilyl trifluoroactate. Those formed only of the mixture may be used.

In the present invention, a method of cleaning the wafer is not particularly limited so long as the liquid chemical or the cleaning liquid can be retained at least in the recessed portions of the uneven pattern of the wafer. As the cleaning method, it is possible to cite: a sheet cleaning method represented by spin cleaning where wafers are cleaned one by one in such a manner as to generally horizontally dispose and rotate them while supplying a liquid to the vicinity of the center of the rotation; and a batch method of immersing two or more wafers in a cleaning bath to clean them. Incidentally, the form of the liquid chemical or the cleaning liquid at the time of supplying the liquid chemical or the cleaning liquid at least to the surfaces of the recessed portions of the uneven pattern of the wafer is not particularly limited as far as it is in the form of liquid at time of being retained in the recessed portions. It is possible to cite, for example, liquid, vapor and the like.

The wafer is a wafer containing silicon element at the surfaces of the recessed portions of the uneven pattern, and includes: those in which at least one component selected from silicon, silicon oxide and silicon nitride forms at least the surfaces of the recessed portions of the wafer; and those in which at least the surfaces of the recessed portions are formed of at least one component selected from silicon, silicon oxide and silicon nitride at the time of forming the uneven pattern. Additionally, the wafer may includes: those in which at least one component selected from silicon, silicon oxide and silicon nitride forms at least a part of the surfaces of the recessed portions of the wafer; and those in which at least a part of the surfaces of the recessed portions is formed of at least one component selected from silicon, silicon oxide and silicon nitride at the time of forming the uneven pattern. In these cases, the water-repellent film is formed on a surface of at least one component selected from silicon, silicon oxide and silicon nitride which component exists at least in the part of the surfaces of the recessed portions. Accordingly, the water-repellent film may be formed on a part of the surfaces of the recessed portions of the uneven pattern of the wafer.

Additionally, the cleaning process of the present invention particularly preferably includes:

(a step 1) a step of making a surface of a wafer into a surface having an uneven pattern, followed by supplying a water-based liquid to the surface and retaining the water-based liquid at least in recessed portions of the uneven pattern;

(a step 2) a step of substituting the water-based liquid retained at least in the recessed portions of the uneven pattern with a cleaning liquid having a boiling point of from 55 to 200° C.;

(a step 3) a step of substituting the cleaning liquid with a water-repellent liquid chemical and retaining the liquid chemical at least in the recessed portions of the uneven pattern;

(a step 4) a step of drying the surface of the uneven pattern to remove the liquid therefrom; and

(a step 5) a step of removing a water-repellent film.

First of all, a water-based liquid is retained at least in recessed portions of uneven pattern, as discussed in the above-mentioned “step 1”. Acid which may be mixed into the water-based liquid is exemplified by inorganic acids and organic acids. Examples of the inorganic acids include hydrogen fluoride, buffered hydrogen fluoride, sulfuric acid, nitric acid, hydrochloric acid, phosphoric acid and the like. Examples of the organic acids include methansulfonic acid, benzenesulfonic acid, p-toluenesulfonic acid, trifluoromethanesulfonic acid, acetic acid, trifluoroacetic acid, pentafluoropropionic acid and the like. Alkali which may be mixed into a cleaning liquid is exemplified by ammonia, choline and the like. The oxidizing agents which may be mixed into the cleaning liquid are exemplified by ozone, hydrogen peroxide and the like.

Then, the water-based liquid retained in the recessed portions is substituted with a cleaning liquid having a boiling point of from 55 to 200° C., as discussed in the above-mentioned “step 2”.

The cleaning liquid is preferably at least one liquid selected from the group consisting of: organic solvents; water; and aqueous solutions obtained by mixing at least one kind selected from the organic solvents, acids, alkalis and oxidizing agents with water.

As examples of the organic solvents used for the cleaning liquid, it is possible to cite hydrocarbons, esters, ethers, ketones, halogen element-containing solvents, sulfoxide-based solvents, alcohols, derivatives of polyalcohols, nitrogen element-containing solvents and the like.

Examples of hydrocarbons are toluene, benzene, xylene, hexane, heptane, octane and the like. Examples of esters are ethyl acetate, propyl acetate, butyl acetate, ethyl acetoacetate and the like. Examples of ethers are diethyl ether, dipropyl ether, dibutyl ether, tetrahydrofuran, dioxane and the like. Examples of ketones are acetone, acetylacetone, methyl ethyl ketone, methyl propyl ketone, methyl butyl ketone, cyclohexanone, isophorone and the like. Examples of the halogen element-containing solvents are: perfluorocarbons such as perfluorooctane, perfluorononane, perfluorocyclopentane, perfluorocyclohexane, hexafluorobenzene and the like; hydrofluorocarbons such as 1,1,1,3,3-pentafluorobutane, octafluorocyclopentane, 2,3-dihydrodecafluoropentane, ZEORORA-H (produced by ZEON CORPORATION) and the like; hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec HFE-7100, Novec HFE-7200, Novec 7300, Novec 7600 (any of these are produced by 3M Limited) and the like; chlorocarbons such as tetrachloromethane and the like; hydrochlorocarbons such as chloroform and the like; chlorofluorocarbons such as dichlorodifluoromethane and the like; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifluoropropene and the like; perfluoroethers; perfluoropolyethers; and the like. Examples of the sulfoxide-based solvents are dimethyl sulfoxide and the like. Examples of the alcohols are methanol, ethanol, propanol, butanol, ethylene glycol, 1,3-propanediol and the like. Examples of the derivatives of polyalcohols are diethylene glycol monoethyl ether, ethylene glycol monomethyl ether, ethylene glycol monobutyl ether, propylene glycol monomethyl ether, propylene glycol monoethyl ether, diethylene glycol monoethyl ether acetate, ethylene glycol monomethyl ether acetate, ethylene glycol monobutyl ether acetate, propylene glycol monomethyl ether acetate, propylene glycol monoethyl ether acetate, diethylene glycol dimethyl ether, diethylene glycol ethylmethyl ether, diethylene glycol diacetate, ethylene glycol diacetate, ethylene glycol diethyl ether, ethylene glycol dimethyl ether and the like. Examples of the nitrogen element-containing solvents are formamide, N,N-dimethylformamide, N,N-dimethylacetamide, N-methyl-2-pyrrolidone, diethylamine, triethylamine, pyridine and the like.

Incidentally, an organic solvent having a boiling point of lower than 55° C. is mixed with water or an organic solvent having a boiling point of not lower than 55° C., thereby adjusting the obtained mixture liquid to have a boiling point of not lower than 55° C. Additionally, an organic solvent having a boiling point exceeding 200° C. is mixed with water or an organic solvent having a boiling point of not higher than 200° C., thereby adjusting the obtained mixture liquid to have a boiling point of not higher than 200° C.

Incidentally, the cleaning liquid is preferably an organic solvent, water, a mixture liquid of water and an organic solvent in view of the cleanliness. Furthermore, it is preferable that the cleaning liquid is the organic solvent since the water-repellent liquid chemical can be supplied to the recessed portions without being brought into contact with water. In particular, the organic solvent preferably contains a water-soluble organic solvent (having a solubility of not smaller than 5 parts by mass relative to 100 parts by mass of water), with which the organic solvent is easily substituted for the water-based liquid.

Incidentally, subsequent to the step of retaining the water-based liquid in the recessed portions (the step 1), the water-based liquid retained at least in the recessed portions of the uneven pattern may be substituted with a liquid (hereinafter sometimes referred to as a rinse liquid A) different from the water-based liquid, and thereafter may advance into the step of substitution with the cleaning liquid (the step 2).

Incidentally, it is possible to use two or more liquids as the rinse liquid A. It is possible to use the rinse liquid A in such a manner as to conduct a substitution with water and then conduct a substitution with an organic solvent (which preferably includes a water-soluble organic solvent).

Then, the water-repellent liquid chemical is retained at least in the recessed portions of the uneven pattern as discussed in the above-mentioned “step 3”, thereby forming the water-repellent film due to the water-repellent liquid chemical on the surfaces of the recessed portions of the uneven pattern. The temperature of the water-repellent liquid chemical is not lower than 40° C. and lower than the boiling point of the water-repellent liquid chemical.

When the water-repellent film is formed on the surfaces of the recessed portions of the uneven pattern of the wafer due to the water-repellent liquid chemical, a contact angle is preferably from 50 to 130° on the assumption that water is retained on the surfaces because the pattern collapse becomes difficult to occur. Additionally, the closer to 90° the contact angle is, the smaller the capillary force acting on the surfaces of the recessed portions becomes. With this, the pattern collapse is made further difficult to occur, so that it is therefore particularly preferable that the contact angle is from 60 to 120°, much more preferably from 70 to 110°. Furthermore, the capillary force is preferably not higher than 2.1 MN/m². The capillary force of not higher than 2.1 MN/m² is preferable because the pattern collapse thereby becomes difficult to occur. Additionally, a lower capillary force makes the pattern collapse further difficult to occur, so that a capillary force is particularly preferably not higher than 1.5 MN/m², much more preferably, much not higher than 1.0 MN/m². Furthermore, it is ideal to put the capillary force close to 0.0 MN/m² as much as possible by adjusting the contact angle to the liquid to around 90°.

Then, the step of drying the surface of the uneven pattern to remove the liquid therefrom is performed, as discussed in the above-mentioned “step 4”. In this step, the liquid retained on the surface of the uneven pattern is removed by drying. The drying is preferably conducted by a conventionally known drying method such as spin drying, IPA (2-propanol) steam drying, Marangoni drying, heating drying, warm air drying, vacuum drying and the like.

Incidentally, subsequent to the step of retaining the water-repellent liquid chemical at least in the recessed portions of the uneven pattern (the step 3), the liquid chemical retained at least in the recessed portions of the uneven pattern may be substituted with a liquid (hereinafter sometimes referred to as a rinse liquid B) different from the liquid chemical, and thereafter may advance into the step of drying the surface of the uneven pattern to remove the liquid therefrom (the step 4).

Additionally, it is possible to use two or more liquids for the substitution, as the rinse liquid B. For example, it is possible to conduct a substitution with an organic solvent (that preferably includes a water-soluble organic solvent) and then conduct a substitution with a water-based liquid, as the rinse liquid B.

Examples of the rinse liquid A and the rinse liquid B include water, an organic solvent, a mixture of water and an organic solvent, those into which at least one kind of acid, alkali and surfactant is mixed, and those to which the silicon compound A and/or the silicon compound B is so added as to have a lower concentration than that of the water-repellent liquid chemical.

Incidentally, the organic solvent discussed as one preferable example of the rinse liquid A and the rinse liquid B is exemplified by hydrocarbons, esters, ethers, ketones, halogen element-containing solvents, sulfoxide-based solvents, alcohols, derivatives of polyalcohols, nitrogen element-containing solvents and the like.

Examples of hydrocarbons are toluene, benzene, xylene, hexane, heptane, octane and the like. Examples of esters are ethyl acetate, propyl acetate, butyl acetate, ethyl acetoacetate and the like. Examples of ethers are diethyl ether, dipropyl ether, dibutyl ether, tetrahydrofuran, dioxane and the like. Examples of ketones are acetone, acetylacetone, methyl ethyl ketone, methyl propyl ketone, methyl butyl ketone, cyclohexanone, isophorone and the like. Examples of the halogen element-containing solvents are: perfluorocarbons such as perfluorooctane, perfluorononane, perfluorocyclopentane, perfluorocyclohexane, hexafluorobenzene and the like; hydrofluorocarbons such as 1,1,1,3,3-pentafluorobutane, octafluorocyclopentane, 2,3-dihydrodecafluoropentane, ZEORORA-H (produced by ZEON CORPORATION) and the like; hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec HFE-7100, Novec HFE-7200, Novec 7300, Novec 7600 (any of these are produced by 3M Limited) and the like; chlorocarbons such as tetrachloromethane and the like; hydrochlorocarbons such as chloroform and the like; chlorofluorocarbons such as dichlorodifluoromethane and the like; hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifluoropropene and the like; perfluoroethers; perfluoropolyethers; and the like. Examples of the sulfoxide-based solvents are dimethyl sulfoxide and the like. Examples of the alcohols are methanol, ethanol, propanol, butanol, ethylene glycol, 1,3-propanediol and the like. Examples of the derivatives of polyalcohols are diethylene glycol monoethyl ether, ethylene glycol monomethyl ether, ethylene glycol monobutyl ether, propylene glycol monomethyl ether, propylene glycol monoethyl ether, diethylene glycol monoethyl ether acetate, ethylene glycol monomethyl ether acetate, ethylene glycol monobutyl ether acetate, propylene glycol monomethyl ether acetate, propylene glycol monoethyl ether acetate, diethylene glycol dimethyl ether, diethylene glycol ethylmethyl ether, diethylene glycol diacetate, ethylene glycol diacetate, ethylene glycol diethyl ether, ethylene glycol dimethyl ether and the like. Examples of the nitrogen element-containing solvents are formamide, N,N-dimethylformamide, N,N-dimethylacetamide, N-methyl-2-pyrrolidone, diethylamine, triethylamine, pyridine and the like.

When removing a liquid from the surface of the uneven pattern, the liquid retained on the surface may be the liquid chemical, the rinse liquid B, or a mixture of these. Incidentally, the mixture containing the liquid chemical may be a liquid which is under a condition where the liquid chemical is on the way to substitution with the rinse liquid B, or may be a mixture liquid obtained by mixing the liquid chemical into the rinse liquid B which is different from the liquid chemical in advance. Additionally, a liquid may be once removed from the surface of the uneven pattern, followed by retaining the rinse liquid B or the mixture liquid on the surface of the uneven pattern, upon which drying may be conducted. By virtue of the presence of the water-repellent film on the surfaces of the recessed portions at the time of removing a liquid from the surface of the uneven pattern, the capillary force acting on the portions is so reduced as to make the pattern collapse difficult to occur.

Incidentally, in the step of drying the surface of the uneven pattern to remove the liquid therefrom (the step 4), it is preferable that the liquid removed from the surface of the uneven pattern is water, the organic solvent or a mixture of these, because stains become difficult to remain on the wafer surface after drying. If the liquid is a water-based liquid, i.e., water in particular, the contact angle θ between this liquid and the surfaces of the recessed portions of the uneven pattern provided with water repellency by the liquid chemical is increased, which is preferable because the capillary force P of the surfaces of the recessed portions is decreased.

Incidentally, it is also preferable to retain the cleaning liquid, the rinse liquid A and the rinse liquid B at a temperature of not lower than 10° C. and lower than the boiling point of the cleaning liquid. For example, it is preferable to use a solution containing an acid aqueous solution, particularly preferably a solution containing an acid aqueous solution and an organic solvent having a boiling point of not lower than 100° C., as the rinse liquid A, and to increase the temperature of the rinse liquid A close to the boiling point of the rinse liquid A; because the water-repellent film can be formed with a short time.

Then, the step of removing a water-repellent film as discussed in the above-mentioned (step 5) is performed. In the case of removing the water-repellent film, it is effective to cleave C—C bond and C—F bond in the water-repellent film. A method therefor is not particularly limited so long as it can cleave the above-mentioned bonds, but exemplified by irradiating the wafer surface with light, heating the wafer, exposing the wafer to ozone, irradiating the wafer surface with plasma, and subjecting the wafer surface to corona discharge and the like.

In the case of removing the water-repellent film by light irradiation, it is preferable to conduct an irradiation with ultraviolet rays having a wavelength of shorter than 340 nm and 240 nm (corresponding to bond energies of C—C bond and C—F bond in the water-repellent film, i.e., 83 kcal/mol and 116 kcal/mol). As the light source therefor, there is used a metal halide lamp, a low-pressure mercury lamp, a high-pressure mercury lamp, an excimer lamp, a carbon arc or the like. In the case of the metal halide lamp, the intensity of the ultraviolet irradiation is preferably not less than 100 mW/cm², particularly preferably not less than 200 mW/cm², as a measurement value obtained by the illuminance meter (Intensity meter UM-10 produced by Konica Minolta Sensing, Inc., Light-Receptor UM-360 [Peak sensitivity wavelength: 365 nm, Measured wavelength range: 310 to 400 nm]). Incidentally, an irradiation intensity of less than 100 mW/cm² takes a long time to remove the water-repellent film. Additionally, in the case of the low-pressure mercury lamp, the ultraviolet irradiation is performed with shorter wavelengths so that removal of the water-repellent film is achieved in a short time even if the intensity is low. This is preferable.

Additionally, in the case of removing the water-repellent film by light irradiation, it is particularly preferable to generate ozone in parallel with decomposition of components of the water-repellent film by ultraviolet rays and then to induce oxidation-volatilization of the components of the water-repellent film by the ozone, since a treatment time is saved thereby. As the light source therefor, the low-pressure mercury lamp or the excimer lamp is used. Additionally, the wafer may be heated while being subjected to light irradiation.

In the case of heating the wafer, the heating of the wafer is conducted at 400 to 700° C., preferably at 500 to 700° C. The heating time therefor is preferably kept from 0.5 to 60 minutes, more preferably from 1 to 30 minutes. Additionally, this step may be conducted in combination with ozone exposure, plasma irradiation, corona discharge or the like. Additionally, the wafer may be heated while being subjected to light irradiation.

In the case of exposing the wafer to ozone, it is preferable to provide ozone generated by ultraviolet irradiation using the low-pressure mercury lamp, low-temperature discharge using high voltages or the like, to the wafer surface. The wafer may be irradiated with light or heated while being exposed to ozone.

In the step of removing the water-repellent film formed on the wafer surface, the removal of the water-repellent film formed on the wafer surface can be efficiently achieved by combination with the light irradiation, heating, ozone exposure, plasma irradiation, corona discharge or the like.

### EXAMPLES

To make a wafer surface into a surface having an uneven pattern is a technique that has been variously studied and has already been established, as discussed in other literatures and the like. Accordingly, in the present invention, evaluations of a water-repellent liquid chemical were mainly performed. Additionally, a pattern collapse greatly depends on the contact angle of the cleaning liquid to the wafer surface, i.e. the contact angle of liquid drop, and on the surface tension of the cleaning liquid, as apparent from the following equation:

P=2×γ×cos θ/S

(In the equation, γ represents the surface tension of a liquid retained in the recessed portions, θ represents the contact angle formed between a liquid retained in the recessed portions and the surfaces of the recessed portions, and S represents the widths of the recessed portions.) In a case of the cleaning liquid retained in recessed portions 4 of an uneven pattern 2, the contact angle of liquid drop and the capillary force of the surfaces of the recessed portions which force is regarded as an equivalent of the pattern collapse are in correlation with each other, so that the capillary force may be derived from the equation and the evaluations made on the contact angle of liquid drop to a water-repellent film. Incidentally, in Examples, a representative of a water-based liquid, i.e., water was used as the cleaning liquid.

However, in a case of the wafer having an uneven pattern at its surface, it is not possible to exactly evaluate the contact angle of the water-repellent film itself, the water-repellent film being formed on the unevenly patterned surface.

The evaluations of the contact angle of waterdrop is conducted by dropping several microliters of waterdrop on a surface of a sample (a substrate) and then by measuring an angle formed between the waterdrop and the substrate surface, as discussed in JIS R 3257 (Testing method of wettability of glass substrate surface). However, in the case of the wafer having a pattern, the contact angle is enormously large. This is because Wenzel's effect or Cassie effect is exhibited and because an apparent contact angle of waterdrop is increased under the influence of a surface shape (roughness) of the substrate upon the contact angle.

In view of the above, in the present example, the liquid chemical is provided to a wafer having a smooth surface to form the water-repellent film on the wafer surface. Then, the water-repellent film is regarded as a water-repellent film 12 formed on a surface of a wafer 1 having an uneven pattern 2 at its surface, thereby carrying out a variety of evaluations. Incidentally, in the present example, a silicon wafer having a smooth surface and having a thermal oxide film layer at the surface was used as a wafer having a smooth surface.

In such a cleaning process as to supply liquid to a wafer while rotating the wafer, it is extremely difficult to precisely replicate a condition of the substitution of the cleaning liquid with the liquid chemical. Hence, in the present example, a wafer that had been immersed in a cleaning liquid was immersed in a liquid chemical under a condition where the cleaning liquid is retained on the surface of the wafer, thereby replicating the substitution condition with great accuracy. Additionally, a time for immersion in the liquid chemical was variously varied in order to change the progress of the substitution, therewith evaluating a water repellency-provided condition (a condition of a water-repellent film) of the wafer.

Details will be discussed below. Hereinafter, there will be discussed: evaluation methods for a wafer to which the water-repellent liquid chemical was provided; preparation of the water-repellent liquid chemical; and evaluation results after providing the water-repellent liquid chemical to the wafer.

[Evaluation Methods for Wafer to which Water-Repellent Liquid Chemical is Provided]

As evaluation methods for a wafer to which a water-repellent liquid chemical is provided, the following evaluations (1) to (2) were performed.

(1) Evaluation of Contact Angle of Water-Repellent Film Formed on Wafer Surface

Pure water of about 2 μl was dropped on a wafer surface on which a water-repellent film is formed, followed by measuring an angle (contact angle) formed between waterdrop and the wafer surface by using a contact angle meter (produced by Kyowa Interface Science Co., Ltd.: CA-X Model). This measurement was conducted at five locations of the wafer surface, followed by calculating a mean value.

(2) Evaluation of Capillary Force

The capillary force (the absolute value of P) was obtained by calculating P by using the following equation.

P=2×γ×cos θ/S

(In the equation, γ represents the surface tension of a liquid retained in recessed portions, θ represents the contact angle between a liquid retained in the recessed portions and surfaces of the recessed portions, and S represents the widths of the recessed portions.)

Incidentally, the present example was made on the assumption that the wafer formed to have a line-and-space pattern of which line width (the widths of the recessed portions) was 45 nm, as an example of a pattern shape. The pattern having a line width of 45 nm tends to cause its collapse in a case where a cleaning liquid used when a gas-liquid interface passes through the wafer is water, while the pattern has difficulty in causing its collapse in a case of 2-propanol. When the pattern widths are 45 nm and the wafer surface is silicon oxide and when the cleaning liquid is 2-propanol (Surface tension: 22 mN/m, Contact angle to silicon oxide: 1°), the capillary force results in 0.98 MN/m². On the other hand, in a case of water (Surface tension: 72 mN/m, Contact angle to silicon oxide: 2.5°) having the largest surface tension among liquids other than mercury, the capillary force results in 3.2 MN/m².

### Example 1-1

(1) Cleaning of Wafer

A wafer having a smooth thermal oxide film (a Si wafer formed having a thermal oxide film of 1 μm thickness on its surface) was immersed in 1 mass % hydrogen fluoride aqueous solution at room temperature for 2 minutes, followed by immersing the wafer in pure water for 1 minute, and then in 2-propanol (iPA) for 1 minute. Accordingly, the cleaning liquid retained on the surface of the wafer is iPA.

(2) Preparation of Water-Repellent Liquid Chemical

In the present example, 5 g of hexamethyldisilazane [(H₃C)₃Si—NH—Si(CH₃)₃] as a silicon compound A, 0.1 g of trimethylsilyl trifluoroactate [(CH₃)₃Si—OC(O)CF₃] as a silicon compound B, and 94.9 g of propylene glycol monomethyl ether acetate (PGMEA) as an organic solvent were mixed thereby obtaining a water-repellent liquid chemical.

(3) Surface Treatment on Surface of Silicon Wafer, with Water-Repellent Liquid Chemical

The water-repellent liquid chemical prepared by the above “(2) Preparation of Water-Repellent Liquid Chemical” section was heated up to 40° C. Then, the wafer prepared by the above “(1) Cleaning of Wafer” section was immersed in the liquid chemical for a variety of periods of time (5, 10, 20, 30, 40, 50 and 60 seconds), thereby forming a water-repellent film thereon. Subsequently, the silicon wafer was taken out of the liquid chemical, followed by immersing the wafer in iPA serving as a rinse liquid for 60 seconds and then in pure water for 60 seconds. Finally, the silicon wafer was taken out of the pure water, followed by spraying air thereon to remove the pure water from the surface.

The thus obtained wafer was evaluated in a manner discussed in the above [Evaluation methods for wafer to which water-repellent liquid chemical is provided] section, therewith investigating a surface treatment time required to make the wafer have a contact angle of not smaller than 75°, that of not smaller than 80°, and that of not smaller than 85° (in other words, a capillary force of not higher than 0.8 MN/m², that of not higher than 0.6 MN/m², and that of not higher than 0.3 MN/m², respectively) after surface treatment. Results thereof are shown in Table 1.

TABLE 1

| | | | | Temperature | Required Time for Surface Treatment | | |
|---|---|---|---|---|---|---|---|
| | Cleaning Liquid used before Water | | | of | (sec) | | |
| | Repellency-Providing Treatment | | | Water- | Contact | Contact | Contact |
| | | Boiling | | Repellent | Angle ≧ 75° | Angle ≧ 80° | Angle ≧ 85° |
| | | Temper- | Temper- | Liquid | (Capillary | (Capillary | (Capillary |
| | | ature | ature | Chemical | Force ≦ 0.8 | Force ≦ 0.6 | Force ≦ 0.3 |
| | Kind | (° C.) | (° C.) | (° C.) | MN/m²) | MN/m²) | MN/m²) |
| Example | iPA | 82 | 25 | 40 | 5 | 10 | 10 |
| 1-1 | | | | | | | |
| Example | iPA | 82 | 25 | 60 | 5 | 10 | 10 |
| 1-2 | | | | | | | |
| Example | iPA | 82 | 25 | 80 | 5 | 10 | 10 |
| 1-3 | | | | | | | |
| Example | PGMEA | 146 | 25 | 80 | 5 | 10 | 10 |
| 1-4 | | | | | | | |
| Comparative | iPA | 82 | 25 | 25 | 10 | 10 | 20 |
| Example | | | | | | | |
| 1-1 | | | | | | | |
| Comparative | DEGEEA | 218 | 25 | 60 | 5 | 10 | 20 |
| Example | | | | | | | |
| 1-2 | | | | | | | |

### Examples 1-2 to 1-4 and Comparative Examples 1-1 and 1-2

Surface treatment of the wafer was conducted upon modifying the temperature of the water-repellent liquid chemical, and the cleaning liquid used before the water repellency-providing treatment from those in Example 1-1, and then evaluation was made thereon. Results are shown in Table 1. Incidentally, PGMEA means propylene glycol monomethyl ether acetate, and DEGEEA means diethylene glycol monoethyl ether acetate.

### Example 2-1

The procedure was the same as that in Example 1-1 with the exception that 5 g of hexamethyldisilazane [(H₃C)₃Si—NH—Si(CH₃)₃] as a silicon compound C, 0.1 g of trifluoroacetic anhydride [{CF₃C(O)}₂O] as an acid C, and 94.9 g of PGMEA as an organic solvent were mixed and reacted thereby obtaining a water-repellent liquid chemical containing trimethylsilyl trifluoroacetate as a silicon compound B, hexamethyldisilazane as the silicon compound A, and PGMEA as the organic solvent. Hexamethyldisilazane contained in the liquid chemical of the present example is the silicon compound C not consumed by the reaction for obtaining the silicon compound B, and is a component which is to function as the silicon compound A. Results thereof are shown in Table 2.

TABLE 2

| | | | | Temperature | Required Time for Surface Treatment | | |
|---|---|---|---|---|---|---|---|
| | Cleaning Liquid used before Water | | | of | (sec) | | |
| | Repellency-Providing Treatment | | | Water- | Contact | Contact | Contact |
| | | Boiling | | Repellent | Angle ≧ 75° | Angle ≧ 80° | Angle ≧ 85° |
| | | Temper- | Temper- | Liquid | (Capillary | (Capillary | (Capillary |
| | | ature | ature | Chemical | Force ≦ 0.8 | Force ≦ 0.6 | Force ≦ 0.3 |
| | Kind | (° C.) | (° C.) | (° C.) | MN/m²) | MN/m²) | MN/m²) |
| Example | iPA | 82 | 25 | 40 | 5 | 10 | 10 |
| 2-1 | | | | | | | |
| Example | iPA | 82 | 25 | 60 | 5 | 10 | 10 |
| 2-2 | | | | | | | |
| Example | iPA | 82 | 25 | 80 | 5 | 10 | 10 |
| 2-3 | | | | | | | |
| Example | PGMEA | 146 | 25 | 60 | 5 | 10 | 10 |
| 2-4 | | | | | | | |
| Comparative | iPA | 82 | 25 | 25 | 10 | 10 | 20 |
| Example | | | | | | | |
| 2-1 | | | | | | | |
| Comparative | DEGEEA | 218 | 25 | 60 | 5 | 10 | 20 |
| Example | | | | | | | |
| 2-2 | | | | | | | |

### Examples 2-2 to 2-4 and Comparative Examples 2-1 and 2-2

Surface treatment of the wafer was conducted upon modifying the temperature of the water-repellent liquid chemical, and the cleaning liquid used before the water repellency-providing treatment from those in Example 2-1, and then evaluation was made thereon. Results are shown in Table 2.

### Example 3-1

The procedure was the same as that in Example 2-1 with the exception that the acid C was modified into trifluoroacetic acid [CF₃C(O)—OH]. Results thereof are shown in Table 3.

TABLE 3

| | | | | Temperature | Required Time for Surface Treatment | | |
|---|---|---|---|---|---|---|---|
| | Cleaning Liquid used before Water | | | of | (sec) | | |
| | Repellency-Providing Treatment | | | Water- | Contact | Contact | Contact |
| | | Boiling | | Repellent | Angle ≧ 75° | Angle ≧ 80° | Angle ≧ 85° |
| | | Temper- | Temper- | Liquid | (Capillary | (Capillary | (Capillary |
| | | ature | ature | Chemical | Force ≦ 0.8 | Force ≦ 0.6 | Force ≦ 0.3 |
| | Kind | (° C.) | (° C.) | (° C.) | MN/m²) | MN/m²) | MN/m²) |
| Example | iPA | 82 | 25 | 40 | 5 | 10 | 10 |
| 3-1 | | | | | | | |
| Example | iPA | 82 | 25 | 60 | 5 | 10 | 10 |
| 3-2 | | | | | | | |
| Example | iPA | 82 | 25 | 80 | 5 | 10 | 10 |
| 3-3 | | | | | | | |
| Example | PGMEA | 146 | 25 | 60 | 5 | 10 | 10 |
| 3-4 | | | | | | | |
| Comparative | iPA | 82 | 25 | 25 | 10 | 10 | 20 |
| Example | | | | | | | |
| 3-1 | | | | | | | |
| Comparative | DEGEEA | 218 | 25 | 60 | 5 | 10 | 20 |
| Example | | | | | | | |
| 3-2 | | | | | | | |

### Examples 3-2 to 3-4 and Comparative Examples 3-1 and 3-2

Surface treatment of the wafer was conducted upon modifying the temperature of the water-repellent liquid chemical, and the cleaning liquid used before the water repellency-providing treatment from those in Example 3-1, and then evaluation was made thereon. Results are shown in Table 3.

### Example 4-1

The procedure was the same as that in Example 1-1 with the exception that trimethylsilyl dimethylamine [(CH₃)₃Si—N(CH₃)₂] was used as the silicon compound A and that the silicon compound B was not used.

TABLE 4

| | | | | Temperature | Required Time for Surface Treatment | | |
|---|---|---|---|---|---|---|---|
| | Cleaning Liquid used before Water | | | of | (sec) | | |
| | Repellency-Providing Treatment | | | Water- | Contact | Contact | Contact |
| | | Boiling | | Repellent | Angle ≧ 75° | Angle ≧ 80° | Angle ≧ 85° |
| | | Temper- | Temper- | Liquid | (Capillary | (Capillary | (Capillary |
| | | ature | ature | Chemical | Force ≦ 0.8 | Force ≦ 0.6 | Force ≦ 0.3 |
| | Kind | (° C.) | (° C.) | (° C.) | MN/m²) | MN/m²) | MN/m²) |
| Example | iPA | 82 | 25 | 40 | 10 | 20 | 60 |
| 4-1 | | | | | | | |
| Example | iPA | 82 | 25 | 60 | 5 | 10 | 50 |
| 4-2 | | | | | | | |
| Example | iPA | 82 | 25 | 80 | 5 | 10 | 20 |
| 4-3 | | | | | | | |
| Example | PGMEA | 146 | 25 | 60 | 5 | 20 | 60 |
| 4-4 | | | | | | | |
| Comparative | iPA | 82 | 25 | 25 | 30 | >60 | >60 |
| Example | | | | | | | |
| 4-1 | | | | | | | |
| Comparative | DEGEEA | 218 | 25 | 60 | 50 | >60 | >60 |
| Example | | | | | | | |
| 4-2 | | | | | | | |

### Examples 4-2 to 4-4 and Comparative Examples 4-1 and 4-2

Surface treatment of the wafer was conducted upon modifying the temperature of the water-repellent liquid chemical, and the cleaning liquid used before the water repellency-providing treatment from those in Example 4-1, and then evaluation was made thereon. Results are shown in Table 4.

### Example 5-1

The procedure was the same as that in Example 4-1 with the exception that octyldimethyl(dimethylamino)silane [C₈H₁₇Si(CH₃)₂—N(CH₃)₂] was used as the silicon compound A. Results thereof are shown in Table 5.

TABLE 5

| | | | | Temperature | Required Time for Surface Treatment | | |
|---|---|---|---|---|---|---|---|
| | Cleaning Liquid used before Water | | | of | (sec) | | |
| | Repellency-Providing Treatment | | | Water- | Contact | Contact | Contact |
| | | Boiling | | Repellent | Angle ≧ 75° | Angle ≧ 80° | Angle ≧ 85° |
| | | Temper- | Temper- | Liquid | (Capillary | (Capillary | (Capillary |
| | | ature | ature | Chemical | Force ≦ 0.8 | Force ≦ 0.6 | Force ≦ 0.3 |
| | Kind | (° C.) | (° C.) | (° C.) | MN/m²) | MN/m²) | MN/m²) |
| Example | iPA | 82 | 25 | 40 | 20 | 20 | 30 |
| 5-1 | | | | | | | |
| Example | iPA | 82 | 25 | 60 | 5 | 10 | 20 |
| 5-2 | | | | | | | |
| Example | iPA | 82 | 25 | 80 | 5 | 5 | 10 |
| 5-3 | | | | | | | |
| Example | PGMEA | 146 | 25 | 60 | 10 | 20 | 20 |
| 5-4 | | | | | | | |
| Comparative | iPA | 82 | 25 | 25 | 60 | >60 | >60 |
| Example | | | | | | | |
| 5-1 | | | | | | | |
| Comparative | DEGEEA | 218 | 25 | 60 | 20 | 30 | 50 |
| Example | | | | | | | |
| 5-2 | | | | | | | |

### Examples 5-2 to 5-4 and Comparative Examples 5-1 and 5-2

Surface treatment of the wafer was conducted upon modifying the temperature of the water-repellent liquid chemical, and the cleaning liquid used before the water repellency-providing treatment from those in Example 5-1, and then evaluation was made thereon. Results are shown in Table 5.

Examples were performed by providing the cleaning liquid used before the water repellency-providing treatment with a boiling point of 55 to 200° C. and by providing the water-repellent liquid chemical with a temperature of not lower than 40° C. and lower than the boiling point of the boiling point of the water-repellent liquid chemical. In the present example, it was confirmed that water-repellency can be provided after a short time. On the contrary, it was confirmed from Comparative Examples that it took time to provide water repellency. In other words, in Comparative Examples, time to achieve the substitution of the cleaning liquid with the liquid chemical was so long as to need an additional time to increase the temperature of the liquid chemical, even if formation of the water-repellent film was accelerated by increasing the temperature of the liquid chemical by conducting the annealing treatment upon completing the substitution; therefore, it was not possible to provide water repellency in such a short time as Examples provided. Additionally, some examples in which the temperature of the liquid chemical was more increased were confirmed to provide water repellency with shorter times.

### EXPLANATION OF REFERENCE NUMERALS

1 Wafer
2 Uneven pattern of a surface of the wafer
3 Projected portions of the pattern
4 Recessed portions of the pattern
5 Widths of the recessed portions
6 Heights of the projected portions
7 Widths of the projected portions
8 Cleaning liquid
9 Water-repellent liquid chemical
10 State where the cleaning liquid and the water-repellent liquid chemical are mixed
11 State where the cleaning liquid is evaporating
12 Water-repellent film

1. A process for cleaning a wafer having an uneven pattern at its surface, comprising the step of:
cleaning the wafer;
substituting a cleaning liquid retained in recessed portions of the wafer with a water-repellent liquid chemical after cleaning; and
drying the wafer,
wherein the cleaning liquid has a boiling point of 55 to 200° C., and
wherein the water-repellent liquid chemical used for the substitution has a temperature of not lower than 40° C. and lower than a boiling point of the water-repellent liquid chemical thereby imparting water repellency at least to surfaces of the recessed portions.

2. A process for cleaning a wafer, as claimed in claim 1, wherein the cleaning liquid is at least one liquid selected from the group consisting of organic solvents, water, and aqueous solutions obtained by mixing at least one kind selected from the organic solvents, acids, alkalis and oxidizing agents with water.

3. A process for cleaning a wafer, as claimed in claim 1,
wherein the wafer contains a silicon element at the surfaces of the recessed portions,
wherein the water-repellent liquid chemical contains a silicon compound A represented by the general formula [1]
R¹ₐSi(H)_{b}X_{4-a-b} [1]
(where R¹ mutually independently represents at least one group selected from a monovalent organic group having hydrocarbon group with 1 to 18 carbon atoms and a monovalent organic group having a fluoroalkyl chain with 1 to 8 carbon atoms, X mutually independently represents a monovalent organic group of which element to be bonded to Si element is nitrogen, a is an integer of from 1 to 3, b is an integer of from 0 to 2, and the total of a and b is 1 to 3)
or the silicon compound A and a silicon compound B, and
wherein the silicon compound B is at least one selected from the group consisting of trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate and octyldimethylsilyl trifluoromethanesulfonate.

4. A process for cleaning a wafer, as claimed in claim 3, wherein the silicon compound A is at least one selected from the group consisting of hexamethyldisilazane, trimethylsilyl dimethylamine, trimethylsilyl diethylamine, tetramethyldisilazane, dimethylsilyl dimethylamine, dimethylsilyl diethylamine, 1,3-dibutyltetramethyldisilazane, butyldimethylsilyl dimethylamine, butyldimethylsilyl diethylamine, 1,3-dihexyltetramethyldisilazane, hexyldimethylsilyl dimethylamine, hexyldimethylsilyl diethylamine, 1,3-dioctyltetramethyldisilazane, octyldimethylsilyl dimethylamine and octyldimethylsilyl diethylamine.

5. A process for cleaning a silicon wafer, as claimed in claim 1, wherein the water-repellent liquid chemical used for the substitution has a temperature of not lower than 70° C. and lower than a temperature represented by (the boiling point of the water-repellent liquid chemical −10° C.).
